(19) United States
(12) Patent Application Publication
(10) Pub. No.: US 2024/0088132 A1
(43) Pub. Date: Mar. 14, 2024

(54) WIDE CHANNEL DIODE STRUCTURE INCLUDING SUB-FIN

(71) Applicant: Intel Corporation, Santa Clara, CA (US)

(72) Inventors: Nicholas A. Thomson, Hillsboro, OR (US); Kalyan C. Kolluru, Portland, OR (US); Ayan Kar, Portland, OR (US); Chu-Hsin Liang, Santa Cruz, CA (US); Benjamin Orr, Beaverton, OR (US); Biswajeet Guha, Hillsboro, OR (US); Brian Greene, Portland, OR (US); Chung-Hsun Lin, Portland, OR (US); Sabih U. Omar, Hillsboro, OR (US); Sameer Jayanta Joglekar, Beaverton, OR (US)

(73) Assignee: Intel Corporation, Santa Clara, CA (US)

(21) Appl. No.: 17/943,819

(22) Filed: Sep. 13, 2022

(51) Int. Cl. H01L 27/02; H01L 29/06; H01L 29/861

(52) U.S. Cl. CPC H01L 27/0255; H01L 29/0673; H01L 29/8611

(57) ABSTRACT

An integrated circuit structure includes a sub-fin having (i) a first portion including a p-type dopant and (ii) a second portion including an n-type dopant. A first body of semiconductor material is above the first portion of the sub-fin, and a second body of semiconductor material is above the second portion of the sub-fin. In an example, the first portion of the sub-fin and the second portion of the sub-fin are in contact with each other, to form a PN junction of a diode. For example, the first portion of the sub-fin is part of an anode of the diode, and wherein the second portion of the sub-fin is part of a cathode of the diode.

### FIELD OF THE DISCLOSURE

The present disclosure relates to integrated circuits, and more particularly, to diode structures.

### BACKGROUND

Diodes are used for many different applications. For example, diodes may be used for electrostatic discharge (ESD) protection in integrated circuit structures. In an example, diodes may be employed to provide ESD protection for input/output (I/O) pins of a given die. Such diodes are capable of sustaining relatively high current densities while imposing relatively low parasitic capacitance to avoid hampering the operation of the pin which they protect. Traditionally, these diodes have been formed by parasitic drain/source-body junctions. A number of non-trivial issues remain with respect to diode structures.

### BRIEF DESCRIPTION OF THE DRAWINGS

FIGS. 1A and 1B illustrate cross-sectional views of a diode structure that includes relatively wide channel regions and sub-fin for current conduction, in accordance with an embodiment of the present disclosure.

FIG. 1C schematically illustrates diodes of the integrated circuit shown in FIGS. 1A-1B, in accordance with an embodiment of the present disclosure.

FIG. 2 illustrates the diode structure of FIGS. 1A-1C being laterally adjacent to a gate-all-around (GAA) transistor structure, where a width of nanoribbons of the diode structure is greater than a width of nanoribbons of the transistor structure, in accordance with some such embodiments.

FIGS. 3A and 3B illustrate cross-sectional views of a diode structure that is at least in part similar to the diode structure of FIGS. 1A-1C, and that includes semiconductor material between adjacent nanoribbons, in accordance with an embodiment of the present disclosure.

FIG. 4 illustrate a flowchart depicting a method of forming the example diode structure of FIGS. 1A and 1B, in accordance with an embodiment of the present disclosure.

FIGS. 5A, 5B, 5C, 5D, 5E, 5F, and 5G collectively illustrate cross-sectional views of an example diode structure (e.g., the diode structure of FIGS. 1A-1C) in various stages of processing, in accordance with an embodiment of the present disclosure.

FIG. 6 illustrates a computing system implemented with integrated circuit structures (such as the diode structures illustrated in FIGS. 1A-3B) formed using the techniques disclosed herein, in accordance with some embodiments of the present disclosure.

As will be appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used. Likewise, while the thickness of a given first layer may appear to be similar in thickness to a second layer, in actuality that first layer may be much thinner or thicker than the second layer; same goes for other layer or feature dimensions.

### DETAILED DESCRIPTION

Integrated circuit structures including diodes are described herein, where a diode includes a p-type sub-fin portion adjacent to an n-type sub-fin portion. In some such cases, an individual sub-fin portion is below a corresponding channel region (such as a fin or a vertical stack of nanoribbons, nanowires, nanosheets), around which a gate structure at least partially wraps. In an example, the channel regions and corresponding sub-fin are made relatively wider (e.g., compared to a width of channel regions and sub-fins of transistors that are laterally adjacent to the diodes), to facilitate higher current conduction path, and to supplement the conduction path through the sub-fin. In one embodiment, an integrated circuit structure comprises a sub-fin having (i) a first portion comprising a p-type dopant and (ii) a second portion comprising an n-type dopant. A first body of semiconductor material is above the first portion of the sub-fin, and a second body of semiconductor material is above the second portion of the sub-fin. In an example, the first portion of the sub-fin and the second portion of the sub-fin are in contact with each other, to form a sub-fin-based PN junction of a diode. For example, the first portion of the sub-fin provides the anode of the diode, and the second portion of the sub-fin provides the cathode of the diode.

In another embodiment, an integrated circuit structure comprises a sub-fin having a first portion comprising a p-type dopant and a second portion comprising an n-type dopant. A first diffusion region is in contact with the first portion of the sub-fin, the first diffusion region comprising p-type dopant. A second diffusion region is in contact with the second portion of the sub-fin, the second diffusion region comprising n-type dopant. In an example, the first portion of the sub-fin and the second portion of the sub-fin are in contact with each other, to form a PN junction.

In yet another embodiment, an integrated circuit structure comprises a sub-fin including (i) a first portion comprising a first type of dopant, (ii) a second portion comprising the first type of dopant, and (iii) a third portion comprising a second type of dopant different from the first type of dopant. A first diffusion region is in contact with the first portion of the sub-fin, a second diffusion region is in contact with the second portion of the sub-fin, and a third diffusion region is in contact with the third portion of the sub-fin. The third portion of the sub-fin is laterally between the first and second portions of the sub-fins. In an example, the third portion of the sub-fin is (i) in contact with the first portion of the sub-fin, to form a first PN junction, and (ii) in contact with the second portion of the sub-fin, to form a second PN junction. Numerous configurations and variations will be apparent in light of this disclosure.

General Overview

As mentioned herein above, there are various non-trivial issues associated with diodes. For example, some diodes utilize the substrate as a primary current path. For example, one possible solution to form ESD diodes uses the formation of doped n-wells or n-type epitaxially grown contacts in, or abutted to, p-wells, or vice versa, to construct a PN junction. The contacts for these p and n-type regions could be placed arbitrarily inside a common substrate with shallow trench isolation (STI) cuts separating them, so as to provide STI-blocked diodes. The physical separation reduces capacitance and leakage in the PN structures. Another possible option might be a gate-blocked lateral diode, which does not depend on the substrate for functionality; rather, the main diode current path is through the channel region (e.g., fin or ribbon) much like a transistor. Such gate-blocked diodes can be formed by doped n-type fins or ribbons or n-type epitaxially grown contacts in, or abutted to, p-type doped fins or ribbons, or vice versa, to construct a PN junction. The n-type contacts are separated from the p-type contacts by the presence of a metal gate. Each of these possible approaches has one or more disadvantages. For instance, an STI-blocked diode approach relies on the presence of a substrate. Unfortunately, substrate-less technologies remove the primary current path for these diodes and thus prevent of the use of a STI-blocked diode approach. Gate-blocked lateral diodes move the primary current path into the channel region. Unfortunately, the formation of the nanoribbons or nanowires removes much of the cross-sectional area through which current can flow resulting in reduced efficiency, thus requiring more diodes to achieve the same level of current conduction.

Accordingly, techniques are described herein to form diode structures. In some examples, the diode structures have low parasitic capacitance, and can sustain high current density, and as thus suitable for ESD diode applications. In one embodiment, the diodes use the sub-fin region for current conduction, and may further supplement that current conduction path with a channel-based condition path. For example, diodes and transistors may be formed to be laterally adjacent to each other. In GAA transistors, the sub-fins may be removed, or at least partially removed, e.g., for backside processing and backside contact formation for the GAA transistors. Such backside contacts may be useful, for example, for stacked GAA transistor architectures. However, in an example, the sub-fin within a diode structure is not removed, and the sub-fin may be used in the diode structure as the primary current conduction path, e.g., in addition to, or instead of, the nanoribbons or other channel region. Furthermore, in an example, the nanoribbons, and consequently the sub-fins (and diffusion regions) of the diode structure, are made wider, e.g., compared to a width of the nanoribbons and sub-fins of the laterally adjacent transistors. The wider sub-fin of the diode structure increases the cross-sectional area of the current conducting paths, and hence, increases the current carrying capability for the diode structure. In an example, diode turn-on resistance may also be improved due to the wider sub-fin area.

A diode structure in accordance with an embodiment comprises a sub-fin including a first portion, a second portion, and a middle portion laterally between the first and second portions. Note that the phrases “portion of the sub-fin” and “sub-fin portion” are used interchangeably. For example, both “first portion of the sub-fin” and “first sub-fin portion” refer to the same portion of the sub-fin. One or more first vertical stacks of nanoribbons are above the first sub-fin portion, one or more second vertical stacks of nanoribbons are above the second sub-fin portion, and one or more middle vertical stacks of nanoribbons are above the middle sub-fin portion. In an example, each nanoribbon extends from a diffusion region of the diode structure. In an example, a diffusion region of the diode structure is an epitaxially grown region, e.g., which may be formed using one or more processes that may also be used to form source or drain regions of the laterally adjacent transistors. Thus, the diffusion regions of a given diode structure are analogous to the source or drain regions of the laterally adjacent transistors. For example, there are a plurality of first diffusion regions that contact the first sub-fin portion, and each of the first vertical stacks of nanoribbons extend from a corresponding one of the first diffusion regions. There is a plurality of second diffusion regions that contact the second sub-fin portion, and each of the second vertical stacks of nanoribbons extend from a corresponding one of the second diffusion regions. Similarly, there is a plurality of middle diffusion regions that contact the middle sub-fin portion, and each of the middle vertical stacks of nanoribbons extend from a corresponding one of the middle diffusion regions.

In one embodiment, the first diffusion regions, the second diffusion regions, the first sub-fin portion, and the second sub-fin portion are doped with a first type of dopant; and the middle diffusion regions and the middle sub-fin portion are doped with a second type of dopant. The first type of dopant comprises one of a p-type dopant or an n-type dopant, and the second type of dopant comprises the other of the p-type dopant or the n-type dopant.

In an example, the middle sub-fin portion is in contact with the first sub-fin portion to form a first PN junction therebetween, and the middle sub-fin portion is also in contact with the second sub-fin portion to form a second PN junction therebetween. Thus, a first diode is formed from the first PN junction, and a second diode is formed from the second PN junction. For example, assume that in the above discussed example, the first type of dopant is a p-type dopant and the second type of dopant is an n-type dopant, although the dopant types may be reversed in another example. In such an example, for the first diode, the first diffusion regions and the first sub-fin portion form the anode of the first diode, and the middle diffusion regions and the middle sub-fin portion form the cathode of the first diode. Similarly, for the second diode, the second diffusion regions and the second sub-fin portion form the anode of the second diode, and the middle diffusion regions and the middle sub-fin portion form the cathode of the second diode. In an example, the first and second diffusion regions are coupled to a first terminal, and the middle diffusion regions are coupled to a second terminal, and the first and second diodes form two parallel diodes between the first and second terminals.

In an example, individual vertical stacks of nanoribbons are wrapped around by a corresponding gate structure that includes a gate electrode and gate dielectric material. In an example, the gate electrodes are floating, and are not coupled to an external circuit or potential. Thus, the gate electrodes do not impart any meaningful functionality within the diode structure, although they allow for a similar gate process to be used in both diode and transistor sections of a given die. In an example, each gate structure is between diffusion regions that are doped with the same type of dopants. For example, a gate structure around the middle stack of nanoribbons is laterally between two middle diffusion regions that are both doped with the same second type of dopants.

In one embodiment, a channel region above a sub-fin portion is laterally separated from another channel region above an adjacent sub-fin portion by dielectric material. For example, as will be discussed below in further detail, a trench filled with the dielectric material separates the channel regions above the two adjacent portions of the sub-fin. In an example, the trench filled with the dielectric material is above a junction of the two adjacent sub-fin portions. The dielectric-filled trench may be in place of a diffusion region. For example, when forming various diffusion regions of the diode structure, the trench region may be covered using a mask, to skip formation of the diffusion region within this particular region.

In one embodiment, various components of the diode structure are formed using one or more processes that may also be used to form laterally adjacent GAA transistor structures. For example, as discussed herein, the diffusion regions of the diodes may be formed using one or more processes that may also be used to form source or drain regions of the GAA transistors. In another example, nanoribbons of both the diode structure and the GAA transistor structures are formed using one or more processes that are common to both structures.

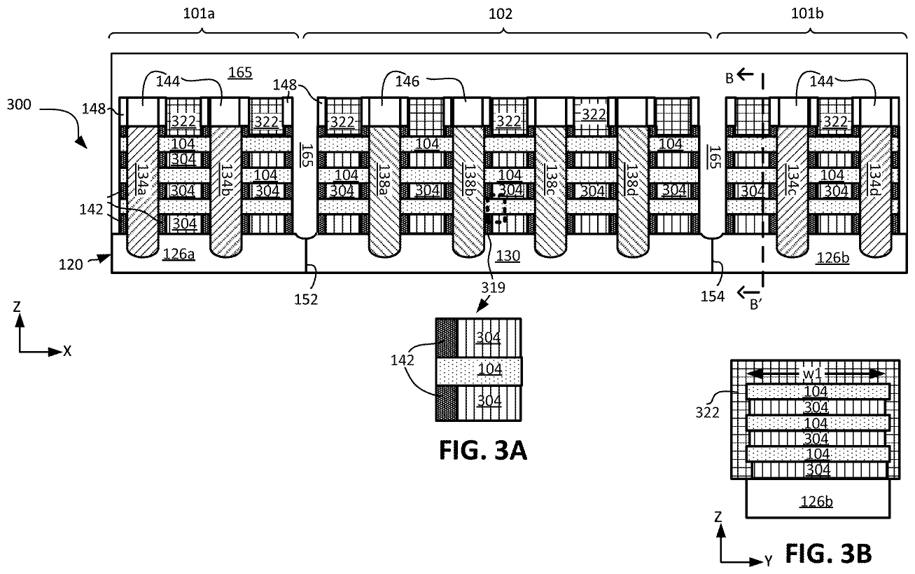

In one embodiment, to form the GAA transistors, initially an alternating stack of channel materials and sacrificial semiconductor materials are formed or otherwise provided. During the nanoribbon release process of the GAA transistors, the layers of sacrificial semiconductor material are removed. However, in an example, in contrast to the transistors, the layers of sacrificial semiconductor material (such as silicon germanium) may not be removed in the diode structure. Thus, the nanoribbons are unreleased and the layers of sacrificial semiconductor material are present in the final diode structure. If the nanoribbons are unreleased, then the gate structure materials deposit on the top and sides of the fin structure that includes both the nanoribbons and the sacrificial semiconductor materials, in a tri-gate fashion, e.g., see FIGS. 3A and 3B. Thus, the gate structure materials partially, and not fully, wraps around individual nanoribbons. In one such example, the sacrificial semiconductor material between the nanoribbons can further improve the current conductance path of the diode, as current may transmit between adjacent diffusions regions through the semiconductor material making up the channel region, in addition to through the sub-fin.

The use of “group IV semiconductor material” (or “group IV material” or generally, “IV”) herein includes at least one group IV element (e.g., silicon, germanium, carbon, tin), such as silicon (Si), germanium (Ge), silicon-germanium (SiGe), and so forth. The use of “group III-V semiconductor material” (or “group III-V material” or generally, “III-V”) herein includes at least one group III element (e.g., aluminum, gallium, indium) and at least one group V element (e.g., nitrogen, phosphorus, arsenic, antimony, bismuth), such as gallium arsenide (GaAs), indium gallium arsenide (InGaAs), indium aluminum arsenide (InAlAs), gallium phosphide (GaP), gallium antimonide (GaSb), indium phosphide (InP), gallium nitride (GaN), and so forth. Note that group III may also be known as the boron group or IUPAC group 13, group IV may also be known as the carbon group or IUPAC group 14, and group V may also be known as the nitrogen family or IUPAC group 15, for example.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the material has an element that is not in the other material.

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For example, in some embodiments, such tools may be used to detect a diode structure comprising (i) a first sub-fin portion and a second sub-fin portion comprising a first type of dopants, and (ii) a middle sub-fin portion comprising a second type of dopants, wherein the first type of dopant comprises one of a p-type dopant or an n-type dopant, and the second type of dopant comprises the other of the p-type dopant or the n-type dopant. In an example, the middle sub-fin portion is in contact with the first sub-fin portion to form a first PN junction, and the middle sub-fin portion is also in contact with the second sub-fin portion to form a second PN junction. In an example, one or more vertical stacks of nanoribbons are above each corresponding sub-fin portion. In an example, each nanoribbon extends from a diffusion region, where the diffusion region is in contact with a corresponding sub-fin portion. In an example, each nanoribbon and corresponding sub-fin portion has a cross-sectional width that is orthogonal to a length of the nanoribbon, where the width is at least 10% more than a width of a channel region (e.g., a nanoribbon) of a transistor that is laterally adjacent to the diode structure. Numerous configurations and variations will be apparent in light of this disclosure.

Architecture

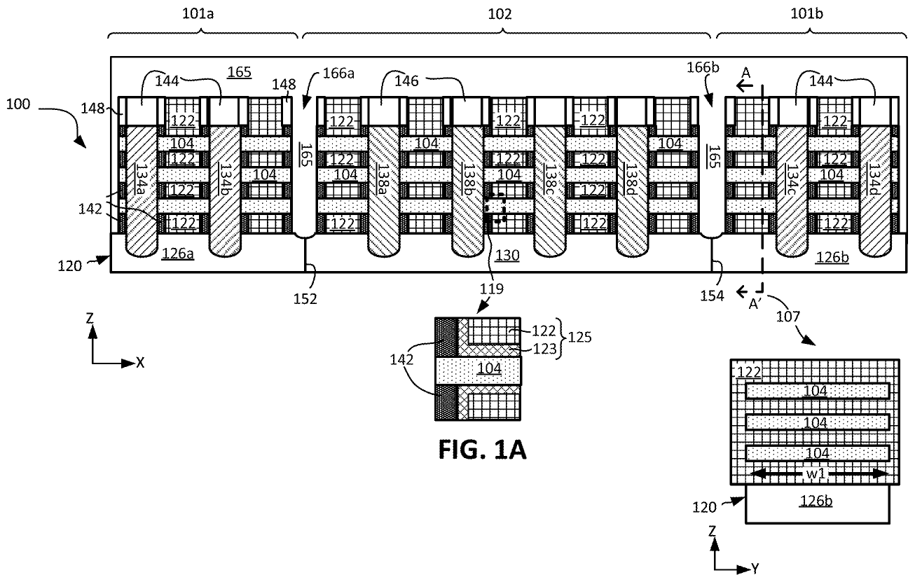

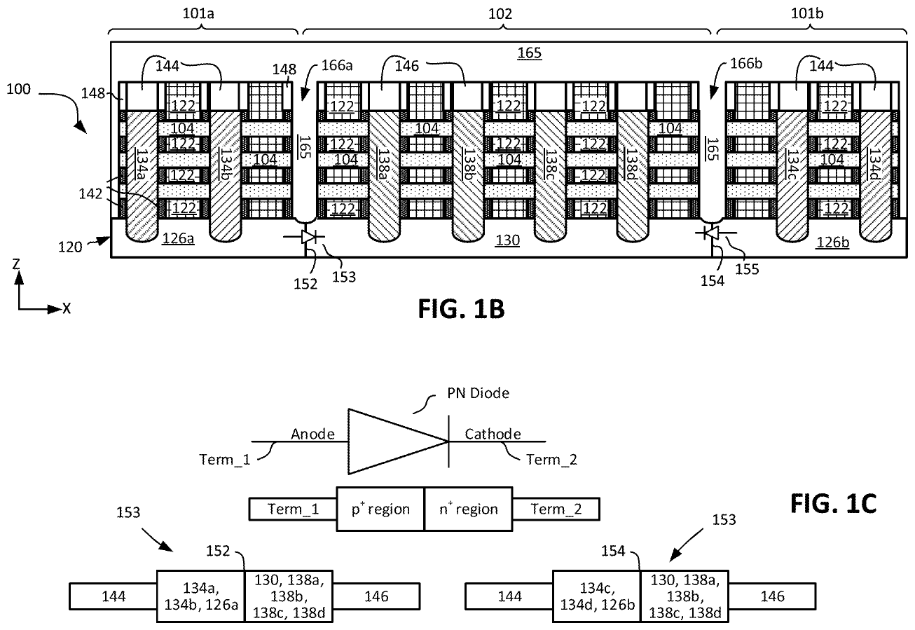

FIG. 1A is a cross-sectional view of a diode structure 100 that includes (i) relatively wide channel regions 104 and (ii) a sub-fin 120 comprising sub-fin portions 126a, 130, 126b for current conduction, in accordance with an embodiment of the present disclosure. As can be seen, the cross-sectional view of FIG. 1A is taken parallel to, and through, the channel regions, such that the channel regions 104, and epitaxially formed diffusion regions 134, 138 (which would be analogous to source and drain regions of a GAA transistor) are shown. A right-bottom portion of FIG. 1A illustrates another cross-sectional view 107 that is along line A-A′ of FIG. 1A, and illustrates one stack of channel regions 104 and a gate electrode 122. For example, the cross-sectional view 107 in right-bottom portion of FIG. 1A is that of the channel regions 104.

In the example of FIG. 1A, the diode structure 100 includes three main sections—section 101a, section 101b, and section 102 laterally between the sections 101a and 101b. The sections 101a and 101b, in the example of FIG. 1A, have same type of doping in corresponding diffusion regions 134 and sub-fin portions 126a, 126b. For example, section 101a comprises diffusion regions 134a and 134b and a portion 126a of the sub-fin 120, where the diffusion regions 134a and 134b and the portion 126a are doped with p-type dopants. Similarly, section 101b comprises diffusion regions 134c and 134d and a portion 126b of the sub-fin 120, which are also doped with p-type dopants. On the other hand, section 102 comprises diffusion regions 138a, 138b, 138c, 138d and portion 130 of the sub-fin 120, which are doped with n-type dopants. In FIG. 1A, the middle section 102 comprising n-type diffusion regions and sub-fin portion is laterally between two end sections 101a, 101b each comprising p-type diffusion regions and sub-fin portions. However, in another example, the sections 101a and 101b may be clubbed together in a middle section, and the section 102 may be separated in two end sections. The placement of p-type and n-type sections may be arbitrary in nature. In an example, there may be a p-type section laterally followed by an n-type section, laterally followed by another p-type section, laterally followed by another n-type section. In another example, the placement of the p-type and n-type sections may be rather arbitrary.

Note that individual sections of the diode structure 100 is somewhat similar to a GAA transistor architecture. For example, in a GAA transistor architecture, one or more channel regions (such as nanoribbons, nanosheets, or nanowires) extend between doped source region and drain region, where a gate structure wraps around individual channel regions. Similarly, in the diode structure 100, such as in section 101a of the diode structure 100, one or more (such as a plurality of) channel regions 104 extend between doped diffusion regions 134a and 134b, with a gate structure 125 (which includes gate electrode 122 and gate dielectric 123) on (e.g., at least partly wrapping around) individual channel regions 104. Thus, each of the doped diffusion regions 134a, 134b is somewhat analogues to a source or a drain region of a GAA transistor (although note that there is no specific source or drain regions in a diode structure). Accordingly, for ease of identification, each of the regions 134a, 134b (and also regions 134c, 134d, 138a, 138b, 138c, 138d) is referred to herein as a source or drain region, and are also referred to herein as a “diffusion region”. Similarly, for ease of identification, regions 104 comprising bodies of semiconductor materials are also referred to herein as channel regions (although note that there may not be any specific channel region in a diode structure). In an example, the regions 104 comprise one or more semiconductor material, and each of the regions 104 is also referred to herein as a body or chunk of semiconductor materials.

Note that the channel regions 104 in the example of FIG. 1A are in the form of nanoribbons. As will be appreciated in light of this disclosure, reference to nanoribbons as channel regions is also intended to include other gate-all-around or multi-gate channel regions, such as nanowires, nanosheets, and other such semiconductor bodies around which a gate structure can wrap, and may also include fin based channel region around which a gate structure can partially wrap. To this end, the use of a specific channel region configuration (e.g., nanoribbon) is not intended to limit the present description to that specific channel configuration. Rather, the techniques provided herein can benefit any number of channel configurations, whether those bodies be nanowires, nanoribbons, nanosheets or some other body around which a gate structure can at least partially wrap (such as the semiconductor bodies of a forksheet device or a fin-based device). For example, in one example, individual vertical stacks of nanoribbon channel regions may be replaced by a corresponding fin, and the diode structure 100 may thus include fin based structures as well.

The particular cross-section of FIG. 1A includes three channel regions 104 extending between any two adjacent diffusion regions of a section (e.g., a vertical stack of three channel regions or nanoribbons 104). However, any number of channel regions can be included in each of the sections 101a, 101b, 102, as will be appreciated. For example, a single channel region, such as a fin based structure, may also be possible. Similarly, section 101a comprises two diffusion regions 134a, 134b, section 101b comprises two diffusion regions 134c, 134d, and section 102 comprises four diffusion regions 138a, 138b, 138c, 138d, but each section may include any different number of such diffusion regions. In an example, a number of diffusion regions in each of the sections 101a and 101b (e.g., two in FIG. 1A) are the same, and/or a sum of a number of diffusion regions 134 in sections 101a, 101b (e.g., four in FIG. 1A) is equal to a number of diffusion regions 138 in section 102, e.g., so as to distribute substantially equal and/or balanced currents across two diodes 153, 155 (see FIGS. 1B and 1C below for discussion about the diodes).

With further reference to FIG. 1A, the section 101a includes diffusion regions 134a, 134b, each adjacent to and in contact with one or more channel regions 104 (e.g., nanoribbons 104) on either side. Other embodiments may not have channel regions to each side, such as the example case where only the channel regions between the diffusion regions 134a, 134b is present in the section 101a. In an example, at least remnants of channel regions may be on one or both sides of a diffusion region.

As will be discussed herein in further detail below, each section includes a corresponding portion of the sub-fin 120, above which corresponding nanoribbons 104 are vertically stacked. For example, the section 101a includes the sub-fin portion 126a, the section 102 includes the sub-fin portion 130, and the section 101b includes the sub-fin portion 126b.

A gate structure 125 contacts and at least in part surrounds each nanoribbon 104. In the example of FIG. 1A where the channel region comprises released nanoribbons (or released nanowires or nanosheets or other GAA channel regions), a gate structure 125 fully surrounds or wraps around corresponding individual nanoribbons. Note that in contrast, in the example of FIGS. 3A and 3B, the gate structure only partially wraps around individual “unreleased” nanoribbons, as will be discussed herein below. In yet another example where the channel region is a fin, the gate structure 125 partially wraps around and is on the fin.

Referring again to FIG. 1A, the gate structure 125 includes gate dielectric 123, and gate electrode 122. Note that the gate dielectric 123 is not illustrated in any of the sections 101a, 101b, 102 for purposes of illustrative clarity, but is illustrated in an expanded view of a portion 119. Similarly, the gate structure 125 is specifically labelled in the expanded view of the portion 119

In an example, the gate dielectric 123 may include a single material layer or multiple stacked material layers. In some embodiments, gate dielectric 123 includes a first dielectric layer such as silicon oxide, and a second dielectric layer that includes a high-K material such as hafnium oxide. According to some embodiments, the doping element used in gate dielectric is lanthanum. The gate dielectric 123 is present around middle regions of each nanoribbon, and although not illustrated, may also be present over sub-fin portions 126a, 130, 126b. In some embodiments and although not illustrated in FIG. 1A, one or more work function metals may be included around the individual nanoribbons of the structure 100.

According to some embodiments, in the example of FIG. 1A, a gate electrode 122 extends over and at least partially wraps around corresponding individual nanoribbons 104. Gate electrode 122 may include any sufficiently conductive material such as a metal, metal alloy, or doped polysilicon.

As seen in FIG. 1A, the structure 100 also includes inner gate spacers 142, each of which is laterally between and separates individual diffusion regions 134 or 138 and the gate electrode 122. The inner gate spacers 142 isolate a gate electrode 122 from adjacent diffusion regions. The inner gate spacers 142 comprise an appropriate dielectric material, such as silicon nitride, or oxynitride or oxycarbonitride. The structure 100 also includes gate spacers 148 comprising dielectric material, where the gate spacers are above the inner gate spacers 142. In an example, individual gate spacer 148 separates a corresponding contact 144 or 146 of a corresponding diffusion region 134 or 138, respectively, from the gate electrode 122. In an example, the inner gate spacers 142 and the gate spacers 148 are compositionally and/or elementally same. In another example, the inner gate spacers 142 and the gate spacers 148 may be are compositionally and/or elementally different.

In an example, the gate structures 125 of the structure 100, including the gate electrodes 122, are electrically floating. For example, the gate electrodes 122 are not contacted, and are not coupled to any external electrical circuits. Accordingly, there is no potential applied to the gate electrodes 122. For example, as the structure 100 is a diode, there is no need for the gate electrodes 122, and hence, the gate electrodes 122 are electrically floating and non-functional. In an example, as the gate electrodes 122 are electrically floating, the diode structure 100 may lack any gate contact.

For example, the diode structure 100 is formed to be laterally adjacent to a plurality of transistors (see FIG. 1B for further detail), such as GAA transistors. The transistors and the diode structure 100 are at least in part formed using one or more of the same processes. Because the processes involve forming gate structures across a plurality of adjacent components within a section of the wafer (where the gate structures are functional in one or more of the transistors), the diode structure 100 also includes a gate structure 125.

Similarly, in an example, although the nanoribbons 104 may not substantially contribute to current conduction in the diode structure 100, the nanoribbons 104 are nonetheless present, as a byproduct of formation processes applied to a plurality of laterally adjacent components that includes the diode structure 100 and a plurality of GAA transistors (e.g., where the nanoribbons form channel regions in the transistors).

However, in another example, the gate structure 125, including the gate electrodes 122, may be absent from the structure 100. For example, there may be a polysilicon gate structure (e.g., often referred to as a dummy gate, which is replaced with the final gate structure 100 prior to release of the nanoribbons 104) in place of a corresponding gate structure. Put differently, in such an example, the so called dummy gates of the diode structure 100 may not be replaced by the final replacement metal gate, as will be discussed herein later in further detail. In yet another example, the gate structure 125 may be replaced by dielectric material.

As discussed, the structure 100 includes a plurality of diffusion regions 134 and 138. For example, as discussed above, the diode structure 100 is formed to be laterally adjacent to a plurality of transistor structures (see FIG. 1B for further detail), such as GAA transistors, e.g., using one or more common processes (by common, it is meant that a given process is applied in forming both diode and transistor structures). In an example, the diffusion regions 134 and 138 are formed using one or more processes that may also be used to form source or drain regions in the transistors. Thus, in an example, the diffusion regions 134 and 138 of the diode structure 100 are analogues to the source or drain regions of a GAA transistors.

In some example embodiments, the diffusion regions 134 and 138 are epitaxial regions that are provided after the relevant portion of the fin was isolated and etched away or otherwise removed. In other embodiments, the diffusion regions 134 and 138 may be doped portions of the fin or substrate, rather than epi regions. In some embodiments using an etch and replace process, the epi diffusion regions 134 and 138 are faceted and overgrown from a trench within insulator material (e.g., shallow trench isolation, or gate spacer that deposits on the sides of the fin structure in the diffusion locations), and the corresponding diffusion contact structure 144 or 146 lands on that faceted portion. Alternatively, in other embodiments, the faceted portion of epi diffusion regions 134 and 138 can be removed (e.g., via chemical mechanical planarization, or CMP), and the corresponding diffusion contact structure 144 or 146 lands on that planarized portion.

The diffusion regions 134 and 138 can be any suitable semiconductor material and may include any dopant scheme. For instance, diffusion regions 134 of the sections 101a, 101b may be PMOS regions that include, for example, group IV semiconductor materials such as silicon, germanium, SiGe, germanium tin (GeSn), SiGe alloyed with carbon (SiGe:C). Example p-type dopants include boron, gallium, indium, and aluminum. Diffusion regions 138 of the section 102 can be NMOS regions that include, for example, silicon or group III-V semiconductor materials such as two or more of indium, aluminum, arsenic, phosphorus, gallium, and antimony, with some example compounds including but not limited to indium aluminum arsenide, indium arsenide phosphide, indium gallium arsenide, indium gallium arsenide phosphide, gallium antimonide, gallium aluminum antimonide, indium gallium antimonide, or indium gallium phosphide antimonide. In one specific embodiment, diffusion regions 134a, 134b, 134c, 134d are boron-doped SiGe, and diffusion regions 138a, 138b, 138c, 138d are phosphorus-doped silicon. In a more general sense, the diffusion regions 134 and 138 can be any semiconductor material suitable for a given application.

In some cases, the epi diffusion regions 134 and 138 may include a multilayer structure, such as a germanium cap on a SiGe body, or a germanium body and a carbon-containing SiGe spacer or liner between the corresponding channel region and that germanium body. In any such cases, a portion of the epi diffusion regions 134 and 138 may have a component that is graded in concentration, such as a graded germanium concentration to facilitate lattice matching, or a graded dopant concentration to facilitate low contact resistance. Any number of diffusion region configurations can be used as will be appreciated, and the present disclosure is not intended to be limited to any particular such configurations.

In an example, dielectric material 165, such as inter-layer dielectric (ILD) is on one or more components of the structure 100. In an example, as illustrated, the dielectric material 165 is within a trench 166a that is between right-most nanoribbons 104 that are above the portion 126a of the sub-fin 120 and left-most nanoribbons 104 that are above the portion 130 of the sub-fin 120. Similarly, the dielectric material 165 is within a trench 166b that is between right-most nanoribbons 104 that are above the portion 130 of the sub-fin 120 and left-most nanoribbons 104 that are above the portion 126b of the sub-fin 120.

In an example, the dielectric material 165 within the trench 166a is laterally between the right-most gate structure 125 above the portion 126a and the left-most gate structure 125 above the portion 130, and separates the two gate structures. Similarly, the dielectric material 165 within the trench 166b is laterally between and laterally separates two corresponding gate structures.

As illustrate, in an example, the dielectric material 165 within the trench 166a is above a p-n junction 152 between portions 126a and 130 of the sub-fin 120, and the dielectric material 165 within the trench 166b is above a p-n junction 154 between portions 130 and 126 of the sub-fin 120.

In an example, in at least a portion of an IC including the structure 100, the diffusion regions may be formed having regular pitch, and hence, diffusion regions are ordinarily to be formed within the trenches 166a and 166b based on the pitch. However, during formation of the diffusion regions of the structure 100, the trenches 166a, 166b may be masked off (e.g., protected by a hard mask), to prevent formation of (e.g., to prevent epitaxial growth of) the diffusion regions within the trenches 166a and 166b. The dielectric material 165 within the trench 166a maintains electrical isolation between nanoribbons above the portion 126a and nanoribbons above the portion 130, and the dielectric material 165 within the trench 166b similarly maintains electrical isolation between corresponding nanoribbons.

The semiconductor bodies 104, which in this case are nanoribbons, can be any number of semiconductor materials as well, such as group IV material (e.g., silicon, germanium, or SiGe) or group III-V materials (e.g., indium gallium arsenide). In other embodiments, the semiconductor bodies 104 may be fins on which the corresponding gate structures are formed to provide double-gate or tri-gate configurations (as opposed to gate-all-around configurations with nanoribbons or wires). The semiconductor bodies 104 may be doped, partially doped (e.g., such as the example case where a body 104 is doped at its ends but not in the middle portion), or undoped, and may be shaped or sculpted during the gate formation process, according to some embodiments. In some cases, semiconductor bodies 104 may be a multilayer structure, such as a SiGe body cladded with germanium, or a silicon body cladded with SiGe. Any number of channel configurations can be used.

The contacts 144 for the diffusion regions 134 and the contacts 146 for the diffusion regions 138 can have any number of configurations. In some example embodiments, the contacts 144, 146 include a contact metal and a conductive liner or barrier layer, deposited in a contact trench formed over the source and drain regions. The liner can be, for example, tantalum or tantalum nitride, and metal can be any suitable plug/core material, such as tungsten, aluminum, ruthenium, molybdenum, cobalt, titanium, copper, or alloys thereof. In some cases, the contacts 144, 146 can be optimized p-type and n-type similar to p-type and n-type diffusion regions. For instance, according to some such embodiments, the liner can be titanium for contacts for NMOS diffusion regions 138, or nickel or platinum for contacts for PMOS diffusion region 134. In still other embodiments, the contacts 144, 146 may include resistance reducing materials (e.g., nickel, platinum, nickel platinum, cobalt, titanium, germanium, nickel, gold, or alloys thereof such as germanium-gold alloy, or a multilayer structure of titanium and titanium nitride all have good contact resistance), in addition to contact metal and any liner. Other embodiments may be configured differently.

In an example, the structure 100 includes a sub-fin portion 126a below the nanoribbons 104 of the section 101a, a sub-fin portion 130 below the nanoribbons 104 of the section 102, and a sub-fin portion 126b below the nanoribbons 104 of the section 101b, as illustrated. Note that the various portions of the sub-fin 120 are below the corresponding nanoribbons 104, and may not be present in locations above which the nanoribbons 104 are not present, as illustrated in the cross-sectional view 107 along line A-A′ in the right-bottom portion of FIG. 1A.

In an example, the portions 126a, 126b, 130 of the sub-fin 120 are doped with either p-type or n-type dopants. In the example of FIG. 1A, the portions 126a, 126b of the sub-fin 120 are doped with p-type dopants, and the portion 130 of the sub-fin 120 is doped with n-type dopants. This results in a p-n junction 152 between the sub-fin portions 126a and 130, and another p-n junction 154 between sub-fin portions 126b and 130. This results in formation of diodes 153 and 155 in the junctions 152 and 154, respectively, as illustrated in FIG. 1B. FIG. 1B illustrates a first diode 153 formed by a first p-n junction 152 between sub-fin portions 126a and 130, and a second diode 155 formed by a second p-n junction 154 between sub-fin portions 126b and 130, in accordance with an embodiment of the present disclosure.

In an example where the contacts 144 of the diffusion regions 134a, 134b, 134c, 134d are coupled to a terminal, and where the contacts 146 of the diffusion regions 138a, 138b, 138c, 138d are coupled to another terminal, the diodes 153 and 155 may be in parallel. Thus, in such as an example, the diodes 153 and 155 may be part of an overall diode structure. However, in another example, the diodes 153 and 155 may not be in parallel.

FIG. 1C schematically illustrates two diodes of the structure 100 of FIG. 1A, in accordance with some such embodiments. As can be seen, a PN diode generally includes a PN junction between a first terminal (Term 1) and a second terminal (Term 2). The PN junction includes p-doped (p+) anode region separated from an n-doped (n+) cathode region by a junction. So, and with further reference to FIGS. 1A, 1B, and 1C, for the diode 153, the anode is a combination of the diffusion regions 134a, 134b and the sub-fin portion 126a, and the cathode is a combination of the sub-fin portion 130 and the diffusion regions 138a, 138b, 138c, and 138d, with the junction 152 therebetween. For the diode 155, the anode is a combination of the diffusion regions 134c, 134d and the sub-fin portion 126b, and the cathode is a combination of the sub-fin portion 130 and the diffusion regions 138a, 138b, 138c, and 138d, with the junction 154 therebetween.

In the example of FIG. 1A, the diffusion regions 134a, 134b, 134c, 134d and the sub-fin portions 126a, 126b of the sections 101a and 101b comprise p-type dopants, and the diffusion regions 138a, 138b, 138c, 138d and the sub-fin portion 130 of the section 102 comprise n-type dopants, resulting in the diode structures 153 and 155. However, in another example, the dopant types may be the opposite. Thus, in the other example, the diffusion regions and the sub-fin portions of the sections 101a, 101b may be doped with n-type dopants, and the diffusion regions and the sub-fin portion of the section 102 may be doped with p-type dopants, which will reverse the polarity of the diodes 153, 155 of the diode structure 100, as will be appreciated.

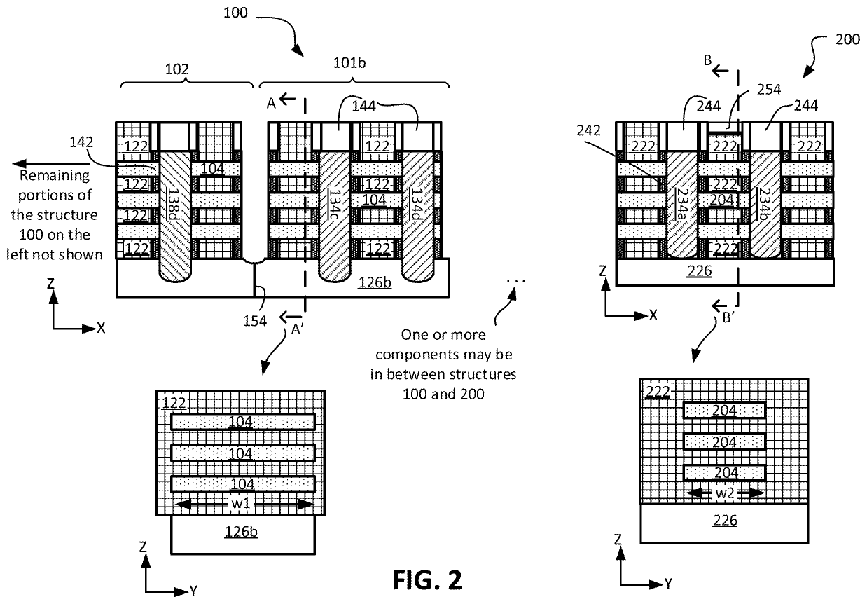

In one embodiment, the nanoribbons 104 have a width w1 measured in a direction that is orthogonal to a direction in which the nanoribbons 104 extend between two adjacent diffusion regions. In an example, the width w1 is wider than widths of nanoribbons of one or more transistors that are laterally adjacent to the structure 100. For example, FIG. 2 illustrates the diode structure 100 of FIGS. 1A-1B being laterally adjacent to a GAA transistor structure 200, where a width of nanoribbons 104 of the diode structure 100 is greater than a width of nanoribbons 204 of the transistor structure 200, in accordance with some such embodiments. Left upper side of FIG. 2 illustrates a cross-section view of the diode structure 100, similar to the view of FIG. 1A. Note that only a portion of the structure 100, which includes entirety of the section 101b and some of the section 102, are illustrated. Left lower side of FIG. 2 illustrates another cross-section view of the diode structure 100 (e.g., along line AA′ of the left upper view), similar to the cross-section view 107 in right-bottom portion of FIG. 1A.

Right upper side of FIG. 2 illustrates a cross-section view of the transistor structure 200, where the cross-section of this view is same as that of FIG. 1A. Note that only some components of the transistor structure 200 are illustrated (e.g., gate dielectric of the transistor structure 100 is not illustrated). Right lower side of FIG. 2 illustrates another cross-section view of the transistor structure 200 (e.g., along line BB′ of the right upper view), similar to the cross-section view 107 in right-bottom portion of FIG. 1A.

The transistor structure 200 comprises a source region 234a and a drain region 234b, nanoribbons 204 extending from the source region 234a to the drain region 234b, source and drain contacts 244, gate electrode 222 wrapping around the nanoribbons 204, and inner gate spacers 242. Note that unlike the electrically floating gate electrode 122 of the diode structure 100, the gate electrode 222 of the transistor structure 200 is electrically coupled to an outside circuit using the gate contact 254.

Furthermore, the diode structure 100 has the sub-fin 120 comprising portions 126a, 126b, and 130. However, in an example, the sub-fin area of the transistor structure 200 may be removed (or at least reduced in height), and replaced by material 226, which may be dielectric material or semiconductor material of a substrate. Thus, in the cross section view of the lower left side, the sub-fin portion 126b is below the nanoribbons 104. On the other hand, in the cross section view of the lower right side, the material 226 is below the nanoribbons 204, and may also be below sections of the transistor structure 200 that doesn't include the nanoribbons.

In an example, the diffusion regions 134, 138 has to be in electrical contact with the corresponding sub-fin portion, e.g., to ensure current conduction for the diodes 153, 155. On the other hand, there may not be substantial current conduction between the source or drain regions 234a, 234b and the material 226. Accordingly, in an example, the diffusion regions 234, 238 may at least in part extend within the corresponding sub-fin portion, as illustrated in FIGS. 1A-2. In contrast, the source or drain regions 234a, 234b may not extend (or extend to a lesser depth) within the material 226, in an example.

As discussed with respect to the cross-sectional view 107 of FIG. 1A, individual nanoribbons 104 of the diode structure 100 has a width of w1. As illustrated in FIG. 2, individual nanoribbons 204 of the transistor structure 200 has a width of w2, where w1 is greater than w2, e.g., multiple times greater than a largest possible value of w2. For example, w1 may be at least 1.2×, at least 1.5×, at least 1.75×, at least 2×, at least 3×, at least 4×, at least 5×, at least 8×, at least 10×, or at least 20× of w2, where “x” here denotes a multiplication or times (e.g., 1.5× implies that w1 is 1.5 times w2). In an example, w1 may be at least 10%, at least 25%, at least 40%, at least 50%, at least 75%, at least 100%, at least 150%, at least 200%, at least 300%, or at least 400% more than w2. In an example, w1 may be at least 1 nm, at least 2 nm, at least 3 nm, at least 4 nm, at least 5 nm, at least 7 nm, at least 8 nm, at least 10 nm, at least 12 nm, at least 15 nm, or at least 20 nm more than w2. In an example, the width w2 of individual nanoribbons 204 may be in the range of 2-50 nm, or in an appropriate subrange thereof, such as in the subrange of 2-5, 2-10, 2-20, 2-40, 5-10, 5-20, 5-40, 5-50, 10-20, 10-40, 10-50, 20-30, 20-50, or 30-50 nm. In an example, the width w1 of individual nanoribbons 104 may be in the range of 8-250 nm or in an appropriate subrange thereof, such as in the subrange of 8-20, 8-50, 8-100, 8-250, 10-20, 10-50, 10-100, 10-200, 20-50, 20-100, 20-200, 20-250, 30-50, 30-100, 30-200, 30-250, 50-100, 50-250, or 100-250 nm.

In an example, wider nanoribbons mean that the corresponding sub-fin 120 is also correspondingly wider. For example, as illustrated in the cross-sectional view 107 of FIG. 1A, the sub-fin portion 126b has also the width of w1. The sub-fin portions 126a and 130 may also similarly have a width of w1. As discussed, the current of the diodes 153 and 155 has to flow though the corresponding sub-fin portions 126a, 126b, and 130. In an example, a wider sub-fin increases cross-sectional area of current conducting paths, and hence, increases current carrying capability for each of the diodes 153, 155. In an example, diode turn-on resistance may also be improved due to the wider sub-fin 120, as the current sees a larger conduction cross-sectional area as it flows to the wider sub-fin 120.

Increasing the current carrying capabilities of the diodes 153, 155, e.g., by using wider sub-fin 120, is particularly beneficial for those applications that require the diodes to carry greater amount of current. For example, the diodes 153, 155 may be used for Electrostatic discharge (ESD) applications. The diodes 153, 155, in an example, are employed to provide ESD protection for integrated circuit input/output (I/O) pins. ESD applications require the diodes to carry high amount of current for a short period of time. Having a wider sub-fin 120 and consequent increase in current carrying capabilities render the diodes 153, 155 suitable for such ESD applications. In other examples, the diodes 153, 155 may also be used for other applications, such as temperature sensing or any other appropriate applications in which diodes are employed.

As illustrated in FIGS. 1A-2, in the structure 100, various diffusion regions are above and in contact with corresponding portions of the sub-fin 120. In an example, as the sub-fin 120 is relatively wide, one or more (or all) of the diffusion regions 134, 138 are also corresponding relatively wide. For example, one or more (or all) of the diffusion regions 134, 138 has the width of w1. In an example, one or more (or all) of the diffusion regions 134, 138 has a width (e.g., width w1) that is greater than a width (e.g., width w2) of source or drain regions 234a, 234b of the transistor 200. For example, the diffusion regions within the diode structure 100 of the die are wider than source or drain regions in other locations of die (e.g., source or drain regions within one or more transistors, such as transistor 200).

FIGS. 3A and 3B illustrate cross-sectional views of a diode structure 300 that is at least in part similar to the diode structure 100 of FIG. 1A, and that includes semiconductor material between adjacent nanoribbons 104, in accordance with an embodiment of the present disclosure. Note that the cross-sectional view of FIG. 3A is similar to the cross-sectional view of FIG. 1A, and the cross-sectional view of FIG. 3B is along line B-B′ of FIG. 3B and is similar to the cross-sectional view 107 of FIG. 1A.

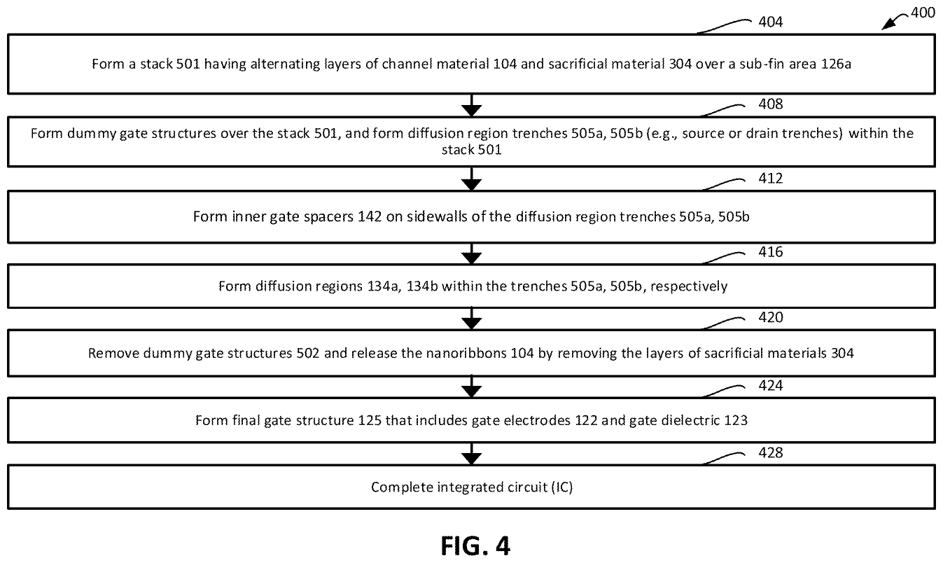

In FIG. 1A, the nanoribbons 104 were fully released when forming the diode structure 100, e.g., by removing sacrificial semiconductor materials 304 between the nanoribbons 104 (e.g., the nanoribbon release process will be discussed herein below with respect to FIG. 4). In contrast, in the diode structure 300 of FIGS. 3A and 3B, the nanoribbons 104 are unreleased, in that semiconductor materials 304 (which are usually sacrificial materials and are released when forming GAA transistors) have not been removed as normally done. Thus, in FIGS. 3A and 3B, a layer of semiconductor material 304 is between two vertically adjacent nanoribbons 104. Thus, the nanoribbons 104 and the semiconductor material 304 form an alternating stack of layers. The semiconductor material 304 comprises, for example, silicon germanium (SiGe) and/or another appropriate semiconductor material.

As such, there is no gate structure wrapped around the nanoribbons 104, in this example embodiment. Instead, there is a high-k metal gate (HKMG) or plug structure 322 on the uppermost nanoribbon 104. By using a standard HKMG 322 (except the nanoribbon release process is skipped), no or otherwise minimal deviation from standard gate processing is required, according to some embodiments. In such cases, note that the gate structure does not impart any meaningful performance benefit to the corresponding diode. In other embodiments, structure 322 may be, for example, a dielectric plug (e.g., silicon dioxide, or porous silicon dioxide). A standard HKMG process is one in which, for example, dummy gate materials are removed from gate trench to expose channel region, sacrificial semiconductor material 304 is removed to release nanoribbons 104, a high-k gate dielectric is conformally deposited onto released nanoribbons 104 and/or exposed areas, and a gate electrode including workfunction material and possibly gate fill metal is then deposited on the gate dielectric. If the nanoribbons 104 are unreleased, as is the case with the diode structure 300 of FIGS. 3A and 3B, then then gate structure materials deposit on the sides of the fin structure that includes both the nanoribbons 104 and the semiconductor materials 304, in a tri-gate fashion, e.g., see FIG. 3B. Thus, the gate structure materials partially, and not fully, wraps around individual nanoribbons 104 in the example of FIGS. 3A and 3B.

In an example, the semiconductor material 304 between the nanoribbons can further improved current conductance path of the diodes 153, 155, as current may transmit between adjacent diffusions regions of a specific section 101a, 101b, or 102, through the semiconductor material 304.

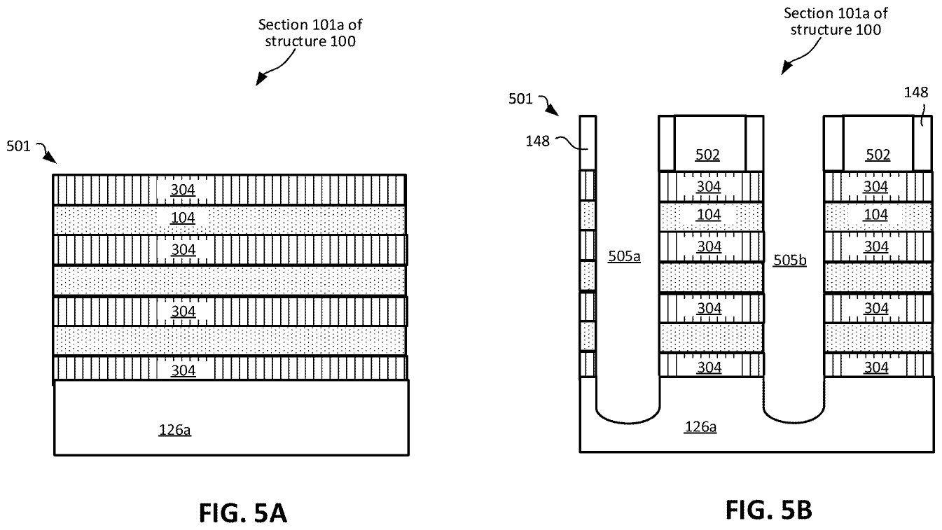

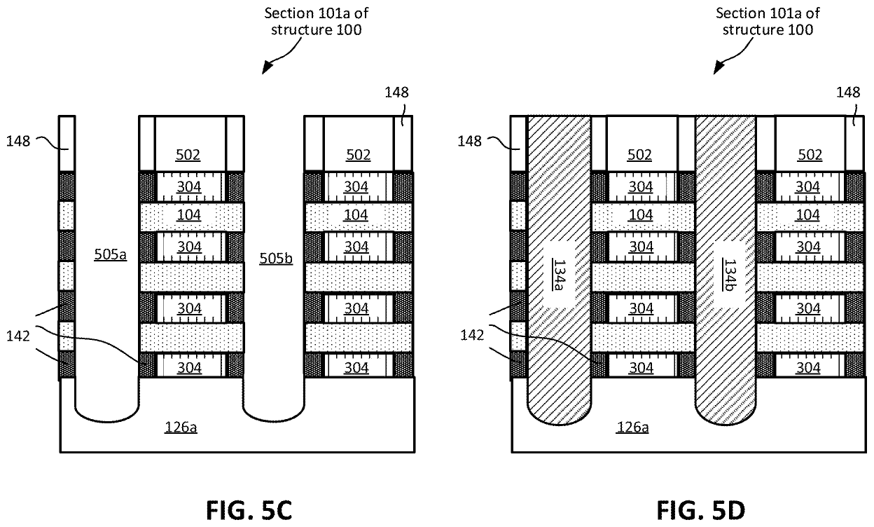

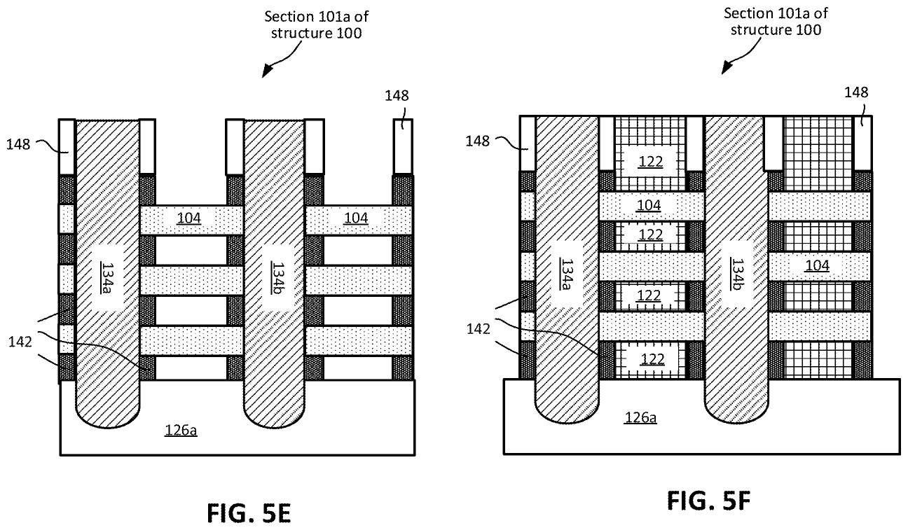

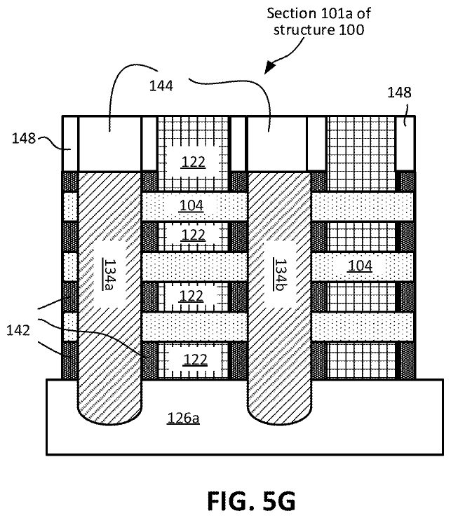

FIG. 4 illustrate a flowchart depicting a method 400 of forming the example diode structure 100 of FIGS. 1A-1B, in accordance with an embodiment of the present disclosure. FIGS. 5A, 5B, 5C, 5D, 5E, 5F, and 5G collectively illustrate cross-sectional views of an example diode structure (e.g., the diode structure 100 of FIGS. 1A-1B) in various stages of processing, in accordance with an embodiment of the present disclosure. FIGS. 4 and 5A-5G will be discussed in unison. The cross-sectional views of FIGS. 5A-5G correspond to the cross-sectional view of FIGS. 1A and 1B.

Note that FIGS. 4 and 5A-5G discuss formation of a section 101a of the diode structure 100. Similar processes may be adapted to form the other sections 101b and/or 102 of the diode structure 100, with appropriate modifications to the processes to account for structural differences between these sections. For example, while the section 101a includes two diffusion regions that are doped with p-type dopants, the section 102 includes four diffusion regions doped with n-type dopants, and the processes of FIGS. 4 and 5A-5G may be appropriately altered to account for such differences, e.g., when forming the section 102.

Referring to FIG. 4, the method 400 includes, at 404, forming a stack 501 having alternating layers of channel material 104 and sacrificial material 304 over a sub-fin portion 126a, as illustrated in FIG. 5A. The various layers may be formed using an appropriate deposition process, such as chemical vapor deposition (CVD), physical vapor deposition (PVD), atomic layer deposition (ALD), vapor-phase epitaxy (VPE), molecular beam epitaxy (MBE), or liquid-phase epitaxy (LPE), for example. As discussed with respect to FIG. 3, the sacrificial material 304 may comprise a semiconductor material, such as SiGe, that is etch selective with respect to the channel material (e.g., Si, or other appropriate semiconductor material, discussed above) of the channel material 104. For example, an etch process to remove the sacrificial material 304 may not substantially etch the channel material 104.

Referring again to FIG. 4, the method 400 then proceeds from 404 to 408, which includes forming dummy gate structures over the stack 501, and forming diffusion region trenches 505a, 505b within the stack 501, as illustrated in FIG. 5B. In an example, the dummy gate structure comprises dummy gate oxide (not labelled in FIG. 5B), dummy gate electrode 502 (e.g., comprising polysilicon, for example), and gate spaces 148. In one embodiment, forming the dummy gate structure may include deposition of a dummy gate oxide, and deposition of a dummy gate electrode 502 (e.g., poly-Si). Gate spacers 148 are formed along opposite sides of the dummy gate electrode 502. For example, the gate spacers 148 comprise silicon nitride (Si₃N₄) and/or other suitable dielectric material, as will be appreciated.

Formation of the diffusion region trenches 505a, 505b may be performed using an appropriate etch process. Note that the diffusion regions will make electrical contact with the sub-fin portion 126a. Accordingly, in an example, the diffusion region trenches 505a, 505b extend at least in part within the sub-fin portion 126a, e.g., such that the later formed diffusion regions will have a better electrical contact with the sub-fin portion 126a. In an example, formation of the diffusion region trenches 505a, 505b may be formed using one or more processes that are performed at least in part in parallel with formation of source or drain trenches for laterally adjacent GAA transistors, such as the GAA transistor 200 of FIG. 2.

Referring again to FIG. 4, the method 400 then proceeds from 408 to 412, where inner gate spacers 142 on sidewalls of the diffusion region trenches 505a, 505b are formed, as illustrated in FIG. 5C. The inner gate spacers 142 may be formed using processes used to form such inner gate spacers in GAA transistors. For example, end portions of the sacrificial materials 304 are etched (e.g., using a wet etch that uses nitric acid/hydrofluoric acid, an anisotropic dry etch, or other suitable etch process) through the trenches 505a, 505b, to form corresponding recesses, and the inner gate spacers 142 are deposited using an appropriate deposition technique (e.g., CVD, PVD, ALD, VPE, MBE, or LPE, for example) within the thus formed recesses. The deposited inner gate spacers 142 may be planarized, such that tips of the channel materials 104 are exposed through the trenches 505a, 505b.

Referring again to FIG. 4, the method 400 then proceeds from 412 to 416, where diffusion regions 134a, 134b are formed within the trenches 505a, 505b, respectively, e.g., as illustrated in FIG. 5D. In an example, the diffusion regions 134 are formed epitaxially within the corresponding trenches. In some embodiments, the diffusion regions may include any suitable doping scheme, such as including suitable n-type and/or p-type dopant (e.g., in a concentration in the range of 1E16 to 1E22 atoms per cubic cm). In the example of the diode structure 100, the diffusion regions 134 are doped with p-type dopants, and the diffusion regions 138 are doped with n-type dopants. In an example, the p-type diffusion regions 134a, . . . , 134d of the sections 101a, 101b may be formed using one or more common (same) processes, and the n-type diffusion regions 138a, . . . , 138d of the section 102 may be formed using another one or more common (same) processes. Thus, the p-type and the n-type diffusion regions are formed one at a time, such that the diffusion regions may be appropriately doped with either p or n type dopants.

Note that when forming the diffusion regions 134a, 134b, no such corresponding diffusion regions are formed within the trenches 166a, 166b (see FIG. 1A). For example, when forming the diffusion regions 134a, 134b, the trenches 166a, 166b may be covered by an appropriate mask (e.g., a hard mask, such as a carbon hard mask), such that no epitaxial growth of diffusion region occurs within the trenches 166a, 166b. As discussed, during subsequent processes of the method 200, the trenches 166a, 166b may be covered by dielectric material 165.

Referring again to FIG. 4, the method 400 then proceeds from 416 to 420, where the dummy gate structures 502 are removed, and the nanoribbons 104 are released by removing the layers of sacrificial materials 304, as illustrated in FIG. 5E. In an example, the dummy gate materials (such as dummy gate dielectric and dummy gate electrodes 502) are removed via an etch process that is selective to the gate spacers 148 and inner gate spacers 142 and other non-gate materials exposed during channel and gate processing. Removing the dummy gate electrode between the gate spacers exposes the channel region of the fin. For example, a polycrystalline silicon dummy gate electrode can be removed using a wet etch process (e.g., nitric acid/hydrofluoric acid), an anisotropic dry etch, or other suitable etch process, as will be appreciated. At this stage of processing, the layer stack of alternating layers of channel material and sacrificial material is exposed in the channel region.

The sacrificial material 304 in the layer stack can then be removed by etch processing, to release the nanoribbons 104, in accordance with some embodiments. Etching the sacrificial material 304 may be performed using any suitable wet or dry etching process such that the etch process selectively removes the sacrificial material and leaves intact the channel material. In one embodiment, the sacrificial material is silicon germanium (SiGe) and the channel material is electronic grade silicon (Si). For example, a gas-phase etch using an oxidizer and hydrofluoric acid (HF) has shown to selectively etch SiGe in SiGe/Si layer stacks. In another embodiment, a gas-phase chlorine trifluoride (ClF3) etch is used to remove the sacrificial SiGe material. The etch chemistry can be selected based on the germanium concentration, nanoribbon dimensions, and other factors, as will be appreciated. After removing the SiGe sacrificial material, the resulting channel region includes silicon nanoribbons extending between the diffusion regions, where ends of the nanoribbons 104 (e.g., silicon) contact the diffusion regions and remain at least partially protected by the gate spacers.

Note that removing the sacrificial material 304 results in eventual formation of the diode structure 100 of FIGS. 1A and 1B. However, in another example, the sacrificial material 304 are not removed and the nanoribbons 104 are not released, which results in eventual formation of the diode structure 300 of FIGS. 3A and 3B.

Referring again to FIG. 4, the method 400 then proceeds from 420 to 424, where the final gate structures 125 including gate electrodes 122 and gate dielectric 123 are formed, as illustrated in FIG. 5F. Note that the gate dielectric 123 and the final gate structures 125 are not separately labelled in FIG. 5F, and FIG. 5F shows the gate electrodes 122. However, the expanded view of a portion 119 of FIG. 1A illustrates and labels the gate dielectric 123 and the final gate structure 125.

Referring again to FIG. 4, the method 400 then proceeds from 424 to 428, where an integrated circuit (IC) is completed. Completing the IC includes one or more other processes, such as forming the diffusion region contacts 144 and/or completing formation of one or more interconnect structures.

Note that the processes in method 400 are shown in a particular order for ease of description. However, one or more of the processes may be performed in a different order or may not be performed at all (and thus be optional), in accordance with some embodiments. Numerous variations on method 400 and the techniques described herein will be apparent in light of this disclosure.

### Example System

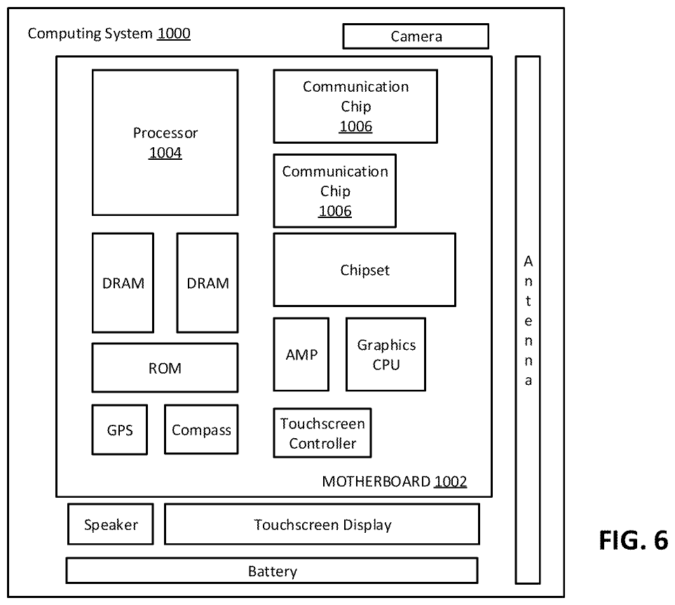

FIG. 6 illustrates a computing system 1000 implemented with integrated circuit structures (such as the diode structures 100 and 300 illustrated in FIGS. 1A-3B) formed using the techniques disclosed herein, in accordance with some embodiments of the present disclosure. As can be seen, the computing system 1000 houses a motherboard 1002. The motherboard 1002 may include a number of components, including, but not limited to, a processor 1004 and at least one communication chip 1006, each of which can be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, etc.

Depending on its applications, computing system 1000 may include one or more other components that may or may not be physically and electrically coupled to the motherboard 1002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or devices formed using the disclosed techniques in accordance with an example embodiment. In some embodiments, multiple functions can be integrated into one or more chips (e.g., for instance, note that the communication chip 1006 can be part of or otherwise integrated into the processor 1004).

The communication chip 1006 enables wireless communications for the transfer of data to and from the computing system 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing system 1000 includes an integrated circuit die packaged within the processor 1004. In some embodiments, the integrated circuit die of the processor includes onboard circuitry that is implemented with one or more integrated circuit structures or devices formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chip 1006 also may include an integrated circuit die packaged within the communication chip 1006. In accordance with some such example embodiments, the integrated circuit die of the communication chip includes one or more integrated circuit structures or devices formed using the disclosed techniques as variously described herein. As will be appreciated in light of this disclosure, note that multi-standard wireless capability may be integrated directly into the processor 1004 (e.g., where functionality of any chips 1006 is integrated into processor 1004, rather than having separate communication chips). Further note that processor 1004 may be a chip set having such wireless capability. In short, any number of processor 1004 and/or communication chips 1006 can be used. Likewise, any one chip or chip set can have multiple functions integrated therein.

In various implementations, the computing system 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device or system that processes data or employs one or more integrated circuit structures or devices formed using the disclosed techniques, as variously described herein. Note that reference to a computing system is intended to include computing devices, apparatuses, and other structures configured for computing or processing information.

### Further Example Embodiments

The following examples pertain to further embodiments, from which numerous permutations and configurations will be apparent.

Example 1. An integrated circuit structure, comprising: a sub-fin having (i) a first portion comprising a p-type dopant and (ii) a second portion comprising an n-type dopant; a first body of semiconductor material above the first portion of the sub-fin; and a second body of semiconductor material above the second portion of the sub-fin; wherein the first portion of the sub-fin and the second portion of the sub-fin are in contact with each other, to form a PN junction.

Example 2. The integrated circuit structure of example 1, further comprising: a first diffusion region in contact with the first portion of the sub-fin, the first diffusion region comprising p-type dopant; and a second diffusion region in contact with the second portion of the sub-fin, the second diffusion region comprising n-type dopant; wherein the first body extends from the first diffusion region towards the second diffusion region, and wherein the second body extends from the second diffusion region towards the first diffusion region.

Example 3. The integrated circuit structure of example 2, wherein the first and second bodies of semiconductor material are each a fin or a nanoribbon.

Example 4. The integrated circuit structure of any one of examples 2-3, comprising: a dielectric structure laterally between and separating the first and second bodies.

Example 5. The integrated circuit structure of example 4, comprising: a first gate structure on the first body of semiconductor material; and a second gate structure on the second body of semiconductor material; wherein the dielectric structure is laterally between and separates the first and second gate structures.

Example 6. The integrated circuit structure of example 5, wherein each of the first and second gate structures is electrically floating and lacks a corresponding gate contact.

Example 7. The integrated circuit structure of any one of examples 4-6, wherein the dielectric structure is above the PN junction.

Example 8. The integrated circuit structure of any one of examples 1-7, wherein the sub-fin and the first and second bodies are part of a diode structure, and wherein the integrated circuit structure further comprises: a transistor structure laterally adjacent to the diode structure, wherein the transistor structure includes (i) a first source or drain region, (ii) a second source or drain region, and (iii) a third body of semiconductor material extending from the first source or drain region to the second source or drain region, wherein the first, second, and third bodies extend in a first direction, wherein the first body has a first width extending in a second direction orthogonal to the first direction, and the third body has a second width extending in the second direction, and wherein the first width is at least 10% more than the second width.

Example 9. The integrated circuit structure of example 8, wherein the first width is at least 25% more than the second width.

Example 10. The integrated circuit structure of any one of examples 1-9, wherein the sub-fin and the first and second bodies are part of a diode structure, and wherein the integrated circuit structure further comprises: a transistor structure laterally adjacent to the diode structure, wherein the transistor structure includes (i) a first source or drain region, (ii) a second source or drain region, and (iii) a third body of semiconductor material extending from the first source or drain region to the second source or drain region, wherein the first, second, and third bodies extend in a first direction, wherein the first body has a first width extending in a second direction orthogonal to the first direction, and the third body has a second width extending in the second direction, and wherein the first width is at least 2 nanometers more than the second width.

Example 11. The integrated circuit structure of example 10, wherein the first width is at least 5 nanometers more than the second width.

Example 12. The integrated circuit structure of any one of examples 1-11, wherein: the first body and the second body extend in a first direction; and the first body has a width extending in a second direction orthogonal to the first direction, the width being at least 8 nm.

Example 13. The integrated circuit structure of any one of examples 1-12, further comprising: a first diffusion region in contact with the first portion of the sub-fin; a second diffusion region in contact with the second portion of the sub-fin, wherein the first body extends from the first diffusion region towards the second diffusion region, and wherein the second body extends from the second diffusion region towards the first diffusion region; wherein the first portion sub-fin and the first diffusion region are an anode of a diode structure, and wherein the second portion of the sub-fin and the second diffusion region are a cathode of the diode structure.

Example 14. The integrated circuit structure of any one of examples 1-13, wherein the first body comprises a first semiconductor material, and the integrated circuit structure further comprises: a third body comprising a second semiconductor material above the first portion of the sub-fin; and a layer of third semiconductor material above the first portion of the sub-fin and between the first body and the third body, such that the first body, the layer, and the third body form a vertical stack above the first portion of the sub-fin; wherein the first and second semiconductor materials are elementally same, and the first and third semiconductor materials are elementally different.

Example 15. The integrated circuit structure of example 14, wherein the first semiconductor material comprises silicon (Si), and the second semiconductor material comprises silicon (Si) and germanium (Ge).

Example 16. The integrated circuit structure of any one of examples 14-15, further comprising: a gate stack comprising a gate electrode, wherein the gate stack partially, and not fully, wraps around the first body, the third body, and the layer of third semiconductor material.

Example 17. The integrated circuit structure of any one of examples 1-16, further comprising: a first plurality of diffusion regions in contact with the first portion of the sub-fin, the first plurality of diffusion regions comprising p-type dopant a second plurality of diffusion regions in contact with the second portion of the sub-fin, the second plurality of diffusion regions comprising n-type dopant; wherein a first number of diffusion regions within the first plurality of diffusion regions is different from a second number of diffusion regions within the second plurality of diffusion regions.

Example 18. The integrated circuit structure of any one of examples 1-17, wherein the PN junction between the first and second portions of the sub-fin is a first PN junction, and wherein the integrated circuit structure further comprises: a third portion of the sub-fin comprising p-type dopant, wherein the second portion of the sub-fin is laterally between the first portion of the sub-fin and the third portion of the third sub-fin; and a third body of semiconductor material above the third first portion of the sub-fin; wherein the second portion of the sub-fin and the third portion of the sub-fin are in contact with each other, to form a second PN junction.

Example 19. The integrated circuit structure of any one of examples 1-18, wherein the PN junction between the first and second portions of the sub-fin is a first PN junction, and wherein the integrated circuit structure further comprises: a third portion of the sub-fin comprising n-type dopant, wherein the first portion of the sub-fin is laterally between the second portion of the sub-fin and the third portion of the third sub-fin; and a third body of semiconductor material above the third first portion of the sub-fin; wherein the first portion of the sub-fin and the third portion of the sub-fin are in contact with each other, to form a second PN junction.

Example 20. An integrated circuit structure, comprising: a sub-fin having a first portion comprising a p-type dopant and a second portion comprising an n-type dopant; a first diffusion region in contact with the first portion of the sub-fin, the first diffusion region comprising p-type dopant; and a second diffusion region in contact with the second portion of the sub-fin, the second diffusion region comprising n-type dopant; wherein the first portion of the sub-fin and the second portion of the sub-fin are in contact with each other, to form a PN junction.

Example 21. The integrated circuit structure of example 20, comprising: a first body of semiconductor material above the first portion of the sub-fin and extending from the first diffusion region toward the second diffusion region; a second body of semiconductor material above the second portion of the sub-fin and extending from the second diffusion region toward the first diffusion region; and a dielectric structure between and separating the first and second bodies.

Example 22. The integrated circuit structure of example 21, wherein the first and second bodies of semiconductor material are each a fin or a nanoribbon.

Example 23. The integrated circuit structure of any one of examples 21-22, comprising: a first gate structure on the first body of semiconductor material; and a second gate structure on the second body of semiconductor material; wherein the dielectric structure is between and separates the first and second gate structures.

Example 24. The integrated circuit structure of example 23, wherein each of the first and second gate structures is electrically floating and lacks a corresponding gate contact.

Example 25. The integrated circuit structure of any one of examples 21-24, wherein the dielectric structure is above the PN junction.

Example 25. An integrated circuit structure, comprising: a sub-fin including (i) a first portion comprising a first type of dopant, (ii) a second portion comprising the first type of dopant, and (iii) a third portion comprising a second type of dopant different from the first type of dopant; and a first diffusion region in contact with the first portion of the sub-fin, a second diffusion region in contact with the second portion of the sub-fin, and a third diffusion region in contact with the third portion of the sub-fin; wherein the third portion of the sub-fin is laterally between the first and second portions of the sub-fins, wherein the third portion of the sub-fin is (i) in contact with the first portion of the sub-fin, to form a first PN junction between the third and first portion of the sub-fins, and (ii) in contact with the second portion of the sub-fin, to form a second PN junction between the third and second portions of the sub-fins.

Example 26. The integrated circuit structure of example 25, wherein the first and second diffusion regions comprise the first type of dopants, and wherein the third diffusion region comprises the second type of dopants.

Example 27. The integrated circuit structure of any one of examples 25-26, further comprising: a first body of semiconductor material above the first sub-fin and extending from the first diffusion region; a second body of semiconductor material above the second sub-fin and extending from the second diffusion region; and a third body of semiconductor material above the third sub-fin and extending from the third diffusion region.

Example 28. The integrated circuit structure of example 27, wherein each of the first, second, and third bodies of semiconductor material comprises a nanoribbon, a nanosheet, a nanowire, or a fin.

Example 29. The integrated circuit structure of any one of examples 27-28, further comprising: a first gate structure on the first body, a second gate structure on the second body, and a third gate structure on the third body, wherein each of the first, second, and third gate structures are electrically floating and lacks a corresponding gate contact.

Example 30. The integrated circuit structure of any one of examples 27-29, wherein the first body comprises a first semiconductor material, and the integrated circuit structure further comprises: a fourth body comprising the first semiconductor material extending from the first diffusion region, wherein the first and fourth bodies form a vertical stack of bodies above the first portion of the sub-fin; and a layer of second semiconductor material between the first body and the fourth body; wherein the first and second semiconductor materials are elementally different.

Example 31. The integrated circuit structure of example 30, wherein the first semiconductor material comprises silicon (Si), and the second semiconductor material comprises silicon (Si) and germanium (Ge).

Example 32. The integrated circuit structure of any one of examples 25-31, wherein the first type of dopant comprises one of a p-type dopant or an n-type dopant, and the second type of dopant comprises the other of the p-type dopant or the n-type dopant.

The foregoing description of example embodiments of the present disclosure has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto.

What is claimed is:

1. An integrated circuit structure, comprising:
a sub-fin having (i) a first portion comprising a p-type dopant and (ii) a second portion comprising an n-type dopant;
a first body of semiconductor material above the first portion of the sub-fin; and
a second body of semiconductor material above the second portion of the sub-fin;
wherein the first portion of the sub-fin and the second portion of the sub-fin are in contact with each other, to form a PN junction.

2. The integrated circuit structure of claim 1, further comprising:
a first diffusion region in contact with the first portion of the sub-fin, the first diffusion region comprising p-type dopant; and
a second diffusion region in contact with the second portion of the sub-fin, the second diffusion region comprising n-type dopant;
wherein the first body extends from the first diffusion region towards the second diffusion region, and wherein the second body extends from the second diffusion region towards the first diffusion region.

3. The integrated circuit structure of claim 2, wherein the first and second bodies of semiconductor material are each a fin or a nanoribbon.

4. The integrated circuit structure of claim 2, comprising:
a dielectric structure laterally between and separating the first and second bodies.

5. The integrated circuit structure of claim 4, comprising:
a first gate structure on the first body of semiconductor material; and
a second gate structure on the second body of semiconductor material;
wherein the dielectric structure is laterally between and separates the first and second gate structures.

6. The integrated circuit structure of claim 5, wherein each of the first and second gate structures is electrically floating and lacks a corresponding gate contact.

7. The integrated circuit structure of claim 4, wherein the dielectric structure is above the PN junction.

8. The integrated circuit structure of claim 1, wherein the sub-fin and the first and second bodies are part of a diode structure, and wherein the integrated circuit structure further comprises:
a transistor structure laterally adjacent to the diode structure, wherein the transistor structure includes (i) a first source or drain region, (ii) a second source or drain region, and (iii) a third body of semiconductor material extending from the first source or drain region to the second source or drain region,
wherein the first, second, and third bodies extend in a first direction,
wherein the first body has a first width extending in a second direction orthogonal to the first direction, and the third body has a second width extending in the second direction, and
wherein the first width is at least 10% more than the second width.

9. The integrated circuit structure of claim 1, wherein the sub-fin and the first and second bodies are part of a diode structure, and wherein the integrated circuit structure further comprises:
a transistor structure laterally adjacent to the diode structure, wherein the transistor structure includes (i) a first source or drain region, (ii) a second source or drain region, and (iii) a third body of semiconductor material extending from the first source or drain region to the second source or drain region,
wherein the first, second, and third bodies extend in a first direction,
wherein the first body has a first width extending in a second direction orthogonal to the first direction, and the third body has a second width extending in the second direction, and
wherein the first width is at least 2 nanometers more than the second width.

10. The integrated circuit structure of claim 1, further comprising:
a first diffusion region in contact with the first portion of the sub-fin;
a second diffusion region in contact with the second portion of the sub-fin, wherein the first body extends from the first diffusion region towards the second diffusion region, and wherein the second body extends from the second diffusion region towards the first diffusion region;
wherein the first portion sub-fin and the first diffusion region are an anode of a diode structure, and wherein the second portion of the sub-fin and the second diffusion region are a cathode of the diode structure.

11. The integrated circuit structure of claim 1, wherein the first body comprises a first semiconductor material, and the integrated circuit structure further comprises:
a third body comprising a second semiconductor material above the first portion of the sub-fin; and
a layer of third semiconductor material above the first portion of the sub-fin and between the first body and the third body, such that the first body, the layer, and the third body form a vertical stack above the first portion of the sub-fin;
wherein the first and second semiconductor materials are elementally same, and the first and third semiconductor materials are elementally different.

12. The integrated circuit structure of claim 11, wherein the first semiconductor material comprises silicon (Si), and the second semiconductor material comprises silicon (Si) and germanium (Ge).

13. The integrated circuit structure of claim 11, further comprising:
a gate stack comprising a gate electrode, wherein the gate stack partially, and not fully, wraps around the first body, the third body, and the layer of third semiconductor material.

14. The integrated circuit structure of claim 1, further comprising:
a first plurality of diffusion regions in contact with the first portion of the sub-fin, the first plurality of diffusion regions comprising p-type dopant;
a second plurality of diffusion regions in contact with the second portion of the sub-fin, the second plurality of diffusion regions comprising n-type dopant;
wherein a first number of diffusion regions within the first plurality of diffusion regions is different from a second number of diffusion regions within the second plurality of diffusion regions.

15. The integrated circuit structure of claim 1, wherein the PN junction between the first and second portions of the sub-fin is a first PN junction, and wherein the integrated circuit structure further comprises:
a third portion of the sub-fin comprising p-type dopant, wherein the second portion of the sub-fin is laterally between the first portion of the sub-fin and the third portion of the third sub-fin; and
a third body of semiconductor material above the third first portion of the sub-fin;
wherein the second portion of the sub-fin and the third portion of the sub-fin are in contact with each other, to form a second PN junction.

16. An integrated circuit structure, comprising:
a sub-fin having a first portion comprising a p-type dopant and a second portion comprising an n-type dopant;
a first diffusion region in contact with the first portion of the sub-fin, the first diffusion region comprising p-type dopant; and
a second diffusion region in contact with the second portion of the sub-fin, the second diffusion region comprising n-type dopant;
wherein the first portion of the sub-fin and the second portion of the sub-fin are in contact with each other, to form a PN junction.

17. The integrated circuit structure of claim 16, comprising:
a first body of semiconductor material above the first portion of the sub-fin and extending from the first diffusion region toward the second diffusion region;
a second body of semiconductor material above the second portion of the sub-fin and extending from the second diffusion region toward the first diffusion region; and
a dielectric structure between and separating the first and second bodies.

18. The integrated circuit structure of claim 16, comprising:
a first gate structure on the first body of semiconductor material; and
a second gate structure on the second body of semiconductor material;
wherein the dielectric structure is between and separates the first and second gate structures.

19. The integrated circuit structure of claim 16, wherein the dielectric structure is above the PN junction.

20. An integrated circuit structure, comprising:
a sub-fin including (i) a first portion comprising a first type of dopant, (ii) a second portion comprising the first type of dopant, and (iii) a third portion comprising a second type of dopant different from the first type of dopant; and
a first diffusion region in contact with the first portion of the sub-fin, a second diffusion region in contact with the second portion of the sub-fin, and a third diffusion region in contact with the third portion of the sub-fin;
wherein the third portion of the sub-fin is laterally between the first and second portions of the sub-fins, wherein the third portion of the sub-fin is (i) in contact with the first portion of the sub-fin, to form a first PN junction between the third and first portion of the sub-fins, and (ii) in contact with the second portion of the sub-fin, to form a second PN junction between the third and second portions of the sub-fins.

21. The integrated circuit structure of claim 20, wherein the first and second diffusion regions comprise the first type of dopants, and wherein the third diffusion region comprises the second type of dopants.

22. The integrated circuit structure of claim 20, further comprising:
a first body of semiconductor material above the first sub-fin and extending from the first diffusion region;
a second body of semiconductor material above the second sub-fin and extending from the second diffusion region; and
a third body of semiconductor material above the third sub-fin and extending from the third diffusion region.

23. The integrated circuit structure of claim 22, wherein the first body comprises a first semiconductor material, and the integrated circuit structure further comprises:
a fourth body comprising the first semiconductor material extending from the first diffusion region, wherein the first and fourth bodies form a vertical stack of bodies above the first portion of the sub-fin; and
a layer of second semiconductor material between the first body and the fourth body;
wherein the first and second semiconductor materials are elementally different.
